(19) United States
(12) Patent Application Publication
(10) Pub. No.: US 2019/0235146 A1
(43) Pub. Date: Aug. 1, 2019

(54) IMAGE DISPLAY DEVICE

(71) Applicant: ZEON CORPORATION, Chiyoda-ku, Tokyo (JP)

(72) Inventor: Kazuhiro OSATO, Tokyo (JP)

(73) Assignee: ZEON CORPORATION, Chiyoda-ku, Tokyo (JP)

(21) Appl. No.: 16/078,012

(22) PCT Filed: Feb. 24, 2017
(86) PCT No.: PCT/JP2017/007096

§ 371 Date: Aug. 29, 2018

(30) Foreign Application Priority Data
Feb. 29, 2016 (JP) 2016-037289

(51) Int. Cl. G02B 5/30; G02F 1/13363; H05B 33/02; G02F 1/1335; H01L 51/50

(52) U.S. Cl. CPC G02B 5/3033; G02F 1/13363; H01L 51/5012; G02F 1/133528; H05B 33/02

(57) ABSTRACT

An image display device including a λ/4 plate, a λ/2 plate, a linear polarizer, and an image display element disposed in this order from a visual recognition side, wherein the λ/2 plate has an NZ factor NZh satisfying 1.5≤NZh.

### FIELD

The present invention relates to an image display device.

### BACKGROUND

An image of an image display device such as a liquid crystal display device may be displayed with linearly polarized light. For example, a liquid crystal display device includes a liquid crystal cell and a linear polarizer. Therefore, an image of the liquid crystal display device is displayed with linearly polarized light having passed through the linear polarizer.

When an image displayed with linearly polarized light as described above is viewed through polarized sunglasses, the image may become dark and cannot be visually recognized in some cases. Specifically, when a vibration direction of linearly polarized light displaying the image is parallel to a polarized light absorption axis of the polarized sunglasses, the linearly polarized light cannot pass through the polarized sunglasses. Therefore, the image cannot be visually recognized. Herein, the vibration direction of the linearly polarized light means a vibration direction of the linearly polarized light in an electric field.

In order to make it possible to visually recognize the image, a λ/4 plate provided on a visual recognition side of a linear polarizer of an image display device has been proposed (Patent Literatures 1 and 2). Linearly polarized light having passed through the linear polarizer is converted into circularly polarized light by the λ/4 plate. A part of the circularly polarized light can pass through the polarized sunglasses. Therefore, the image can be visually recognized through the polarized sunglasses.

A technology of broadband λ/4 plate including a λ/4 plate and a λ/2 plate in combination, like Patent Literatures 3 to 5, has been known.

Like Patent Literature 6, a technology of phase difference film in which a slow axis direction is an in-plane direction of the film and exists in a diagonal direction that is not orthogonal to or parallel to the widthwise direction of the film has been known.

### CITATION LIST

### Patent Literature

Patent Literature 1: Japanese Patent Application Laid-Open No. Hei. 3-174512 A

Patent Literature 2: Japanese Patent Application Laid-Open No. 2005-352068 A

Patent Literature 3: Japanese Patent Application Laid-Open No. 2003-114325 A

Patent Literature 4: Japanese Patent Application Laid-Open No. Hei. 11-183723 A

Patent Literature 5: Japanese Patent Application Laid-Open No. 2014-102440 A

Patent Literature 6: Japanese Patent Application Laid-Open No. 2012-25167 A

### SUMMARY

### Technical Problem

In order to increase the wavelength range of circularly polarized light capable of passing through polarized sunglasses to enhance the visibility of an image, it is desirable that a member capable of converting linearly polarized light into circularly polarized light at a wide wavelength band is used as a λ/4 plate. The present inventor tried to enhance the visibility of an image viewed through polarized sunglasses by preparing a broadband λ/4 plate including a λ/4 plate and a λ/2 plate in combination and providing the broadband λ/4 plate to an image display device. As a result, when the image display device was viewed in a front direction of a display surface, excellent visibility was achieved.

However, when the display surface of the image display device was viewed in an inclined direction, the visibility of the image viewed through polarized sunglasses was poor. Specifically, a color difference ΔE*ab between chromaticity of an image viewed in the inclined direction of the display surface without polarized sunglasses and chromaticity of an image viewed in the inclined direction of the display surface through the polarized sunglasses was large.

The present invention has been made in view of the problems mentioned above, and an object of the present invention is to provide an image display device capable of improving the visibility of an image viewed in an inclined direction of a display surface through polarized sunglasses.

### Solution to Problem

The present inventor has intensively studied to solve the aforementioned problems. As a result, the inventor has found that when an image display device includes a λ/4 plate, a λ/2 plate, a linear polarizer, and an image display element in this order from a visual recognition side and the NZ factor NZh of the λ/2 plate falls within a specific range, the visibility of an image viewed in an inclined direction of a display surface through polarized sunglasses can be improved. Thus, the present invention has been completed.

Specifically, the present invention is as follows.

(1) An image display device comprising a λ/4 plate, a λ/2 plate, a linear polarizer, and an image display element disposed in this order from a visual recognition side, wherein

the λ/2 plate has an NZ factor NZh satisfying 1.5≤NZh.

(2) The image display device according to (1), wherein the NZ factor NZh of the λ/2 plate satisfies 1.5≤NZh≤3.0.

(3) The image display device according to (1) or (2), wherein the λ/4 plate has an NZ factor NZq satisfying 0.95≤NZq≤1.05.

(4) The image display device according to any one of (1) to (3), wherein when an angle of a slow axis of the λ/2 plate relative to a polarized light absorption axis of the linear polarizer is represented by α,

an angle of a slow axis of the λ/4 plate relative to the polarized light absorption axis of the linear polarizer is (2a+45°)±5°.

(5) The image display device according to any one of (1) to (4), wherein an angle a of a slow axis of the λ/2 plate relative to a polarized light absorption axis of the linear polarizer is 15°±5°.

(6) The image display device according to any one of (1) to (5), wherein the λ/2 plate and the λ/4 plate contain the same thermoplastic resin.

(7) The image display device according to any one of (1) to (6), wherein the λ/2 plate and the λ/4 plate contain a norbornene-based resin.

(8) The image display device according to any one of (1) to (7), wherein the λ/2 plate is a diagonally stretched film.

(9) The image display device according to any one of (1) to (8), wherein the λ/2 plate is a sequentially biaxially stretched film.

(10) The image display device according to any one of (1) to (9), wherein the image display element is any of a liquid crystal cell and an organic electroluminescent element.

### Advantageous Effects of Invention

The image display device according to the present invention can improve the visibility of an image viewed in an inclined direction of a display surface through polarized sunglasses.

### BRIEF DESCRIPTION OF DRAWINGS

FIG. 1 is a cross-sectional view schematically illustrating an example of a liquid crystal display device as an image display device according to an embodiment of the present invention.

FIG. 2 is a cross-sectional view schematically illustrating an example of an organic EL display device as an image display device according to another embodiment of the present invention.

FIG. 3 is an exploded perspective view schematically illustrating a relationship between a λ/4 plate, a λ/2 plate, and a linear polarizer in an image display device as an example of the present invention.

FIG. 4 is a perspective view schematically illustrating a state of evaluation model that was set up for calculation of chromaticity in simulations in Examples and Comparative Examples.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, a “long-length” film refers to a film having a length that is 5 times or more the width, and preferably a film having a length that is 10 times or more the width, and specifically refers to a film having a length that allows a film to be wound up into a roll shape for storage or transportation. The upper limit of the length of the long-length film is not particularly limited, and may be, for example, 100,000 times or less the width.

In the following description, an in-plane retardation Re of a film is a value represented by Re=(nx−ny)×d, unless otherwise specified. A thickness-direction retardation Rth of a film is a value represented by Rth={(nx+ny)/2−nz}×d, unless otherwise specified. An NZ factor of a film is a value represented by (nx−nz)/(nx−ny), unless otherwise specified, and may be calculated by a formula of 0.5+Rth/Re. In the formulae, nx represents a refractive index in a direction in which the maximum refractive index is given among directions perpendicular to the thickness direction of the film (in-plane directions), ny represents a refractive index in a direction, among the above-mentioned in-plane directions of the film, orthogonal to the direction giving nx, nz represents a refractive index in the thickness direction of the film, and d represents the thickness of the film. The measurement wavelength is 590 nm unless otherwise specified.

In the following description, a resin having a positive intrinsic birefringence value means a resin of which the refractive index in a stretching direction is larger than the refractive index in a direction orthogonal to the stretching direction, unless otherwise specified. A resin having a negative intrinsic birefringence value means a resin of which the refractive index in the stretching direction is smaller than the refractive index in the direction orthogonal to the stretching direction, unless otherwise specified. The intrinsic birefringence value may be calculated from dielectric constant distribution.

In the following description, a slow axis of a film represents the slow axis in a plane of the film unless otherwise specified.

In the following description, a diagonal direction of a long-length film represents a direction that is an in-plane direction of the film and is not parallel to or perpendicular to the widthwise direction of the film, unless otherwise specified.

In the following description, a front direction of a surface means a normal direction of the surface unless otherwise specified. The front direction specifically represents a direction of polar angle of 0° and azimuth angle of 0° of the surface.

In the following description, an inclined direction of a surface means a direction that is not parallel to or perpendicular to the surface unless otherwise specified. The inclined direction specifically represents a direction within a range of polar angle of the surface of larger than 0° and less than 90°.

In the following description, a direction of an element being “parallel”, “perpendicular”, and “orthogonal” may allow an error within the range of not impairing the advantageous effects of the present invention, for example, within a range of ±5°, unless otherwise specified.

In the following description, “polarizing plate”, “λ/2 plate”, and “λ/4 plate” include not only a rigid member, but also a flexible member such as a resin film, unless otherwise specified.

In the following description, an angle formed between optical axes of a plurality of films in a member including the films (polarized light absorption axis, polarized light transmission axis, slow axis, etc.) represents an angle as viewed in the thickness direction of the films unless otherwise specified.

[1. Summary of Image Display Device]

The image display device of the present invention includes a λ/4 plate, a λ/2 plate, a linear polarizer, and an image display element in this order from a visual recognition side. There are various image display devices according to the types of image display elements. Typical examples thereof may include a liquid crystal display device and an organic electroluminescent display device. Hereinafter, organic electroluminescence may be referred to as “organic EL” as appropriate.

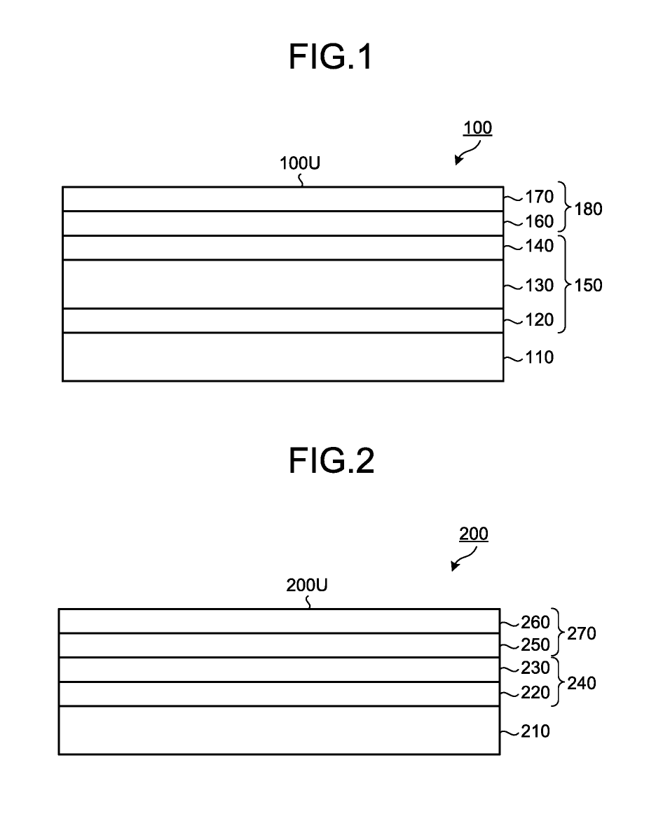

FIG. 1 is a cross-sectional view schematically illustrating an example of a liquid crystal display device as an image display device according to an embodiment of the present invention.

As illustrated in FIG. 1, a liquid crystal display device 100 includes in this order a light source 110; a liquid crystal panel 150 including a light source-side linear polarizer 120, a liquid crystal cell 130 as an image display element, and a visual recognition-side linear polarizer 140; and a broadband λ/4 plate 180 including a λ/2 plate 160 and a λ/4 plate 170. Therefore, the liquid crystal display device 100 includes the λ/4 plate 170, the λ/2 160, the visual recognition-side linear polarizer 140, the liquid crystal cell 130, the light source-side linear polarizer 120, and the light source 110 in this order from the visual recognition side.

The liquid crystal display device 100 displays an image using light that has been emitted from the light source 110 and passed through the light source-side linear polarizer 120, the liquid crystal cell 130, the visual recognition-side linear polarizer 140, and the broadband λ/4 plate 180. Light for displaying an image is linearly polarized light when the light passes through the visual recognition-side linear polarizer 140. When the light passes through the broadband λ/4 plate 180, the light is converted into circularly polarized light. Therefore, with the liquid crystal display device 100, the image is displayed with the circularly polarized light. Accordingly, the image can be visually recognized when the image is viewed in a front direction through polarized sunglasses.

FIG. 2 is a cross-sectional view schematically illustrating an example of an organic EL display device as an image display device according to another embodiment of the present invention.

As illustrated in FIG. 2, an organic EL display device 200 includes in this order an organic EL element 210 as an image display element; a circularly polarizing plate 240 including a λ/4 plate 220 and a linear polarizer 230; and a broadband λ/4 plate 270 including a λ/2 plate 250 and a λ/4 plate 260. Therefore, the organic EL display device 200 includes the λ/4 plate 260, the λ/2 250, the linear polarizer 230, the λ/4 plate 220, and the organic EL element 210 in this order from the visual recognition side.

In the organic EL display device 200, the circularly polarizing plate 240 is usually provided so as to suppress glare of a display surface caused by reflection of external light. Specifically, of light incident from the outside of the device, only a part of linearly polarized light passes through the linear polarizer 230, and then passes through the λ/4 plate 220, resulting in circularly polarized light. The circularly polarized light is reflected on a component that reflects light in the display device (reflection electrode (not shown) in the organic EL element 210, etc.), and then passes through the λ/4 plate 220, resulting in linearly polarized light having a vibration direction orthogonal to a vibration direction of entered linearly polarized light. Thus, the light does not pass through the liner polarizer 230. Accordingly, a function for preventing reflection is achieved (see Japanese Patent Application Laid-Open No. 09-127885 A for a principle of reflection prevention in the organic EL display device). In the example illustrated FIG. 2, the organic EL display device 200 using a single member is shown as the λ/4 plate 220. However, a broadband λ/4 plate including a λ/2 plate and a λ/4 plate in combination may also be used as the λ/4 plate 220.

The organic EL display device 200 displays an image using light that has been emitted from the organic EL element 210 and passed through the λ/4 plate 220, the linear polarizer 230, and the broadband λ/4 plate 270. Light for displaying an image is linearly polarized light when the light passes through the linear polarizer 230. When the light passes through the broadband λ/4 plate 270, the light is converted into circularly polarized light. Therefore, with the organic EL display device 200, the image is displayed with the circularly polarized light. Accordingly, the image can be visually recognized when the image is viewed in the front direction through polarized sunglasses.

In the image display device of the present invention such as the liquid crystal display device 100 and the organic EL display device 200, the λ/2 plates 160 and 250 included in the broadband λ/4 plates 180 and 270, respectively, have an NZ factor NZh within a specific range. The specific NZ factor NZh of the λ/2 plates 160 and 250 is usually 1.5 or more, preferably 1.6 or more, more preferably 2.0 or more, and particularly preferably 2.2 or more, and is preferably 3.5 or less, more preferably 3.0 or less, and particularly preferably 2.8 or less.

When the NZ factor NZh of the λ/2 plates 160 and 250 falls within the aforementioned range, visibility of an image viewed in an inclined direction of a display surface (for example, a display surface 100U of the liquid crystal display device 100 and a display surface 200U of the organic EL display device 200) of the image display device through polarized sunglasses can be improved. Specifically, the color difference ΔE*ab between chromaticity of an image viewed in the inclined direction of the display surface through polarized sunglasses and chromaticity of an image viewed in the inclined direction of the display surface without polarized sunglasses can be decreased. Such a small value of the color difference ΔE*ab is indicative of the fact that the image that is viewed through polarized sunglasses is fairly identical at a good level with the image viewed without polarized sunglasses. Accordingly, when the color difference ΔE*ab can be decreased, the display quality during viewing an image in the inclined direction of the display surface through polarized sunglasses can be improved.

The chromaticity may be determined by measuring the spectrum of light for displaying an image, multiplying this spectrum by spectral sensitivities corresponding to human eye (color-matching functions) to determine tristimulus values X, Y, and Z, and calculating chromaticity (a*, b*, L*). The color difference ΔE*ab may be determined by the following expression (1) from chromaticity (a0*, b0*, L0*) in the view of an image without polarized sunglasses and chromaticity (a1*, b1*, L1*) in the view of the image through polarized sunglasses.

ΔE*ab=\sqrt{(L1*−L0*)²+(a1*−a0*)²+(b1*−b0*)²} (1)

A light polarization state of light for displaying an image may vary depending on an azimuth angle. When an image is viewed in the inclined direction of the display surface through polarized sunglasses, chromaticity to be measured may vary depending on the azimuth angle. Therefore, the color difference ΔE*ab may also vary. Therefore, when the visibility of an image viewed in the inclined direction of the display surface through polarized sunglasses is evaluated, it is preferable that the visibility evaluation is performed on the basis of the average of color differences ΔE*ab obtained by observation in a plurality of azimuth angle directions. Specifically, the color differences ΔE*ab are measured at an interval of azimuth angle direction of 5° within a range of azimuth angle φ of 0° or more and less than 360° (see FIG. 4). The visibility is evaluated by average of the measured color difference ΔE*ab (average color difference). A smaller value of the average color difference is indicative of better visibility of an image viewed in the inclined direction of the display surface through polarized sunglasses.

[2. λ/2 plate]

In the following, a λ/2 plate such as the λ/2 plates 160 and 250 according to the embodiments illustrated in FIGS. 1 and 2 will be described.

The in-plane retardation of the λ/2 plate may be appropriately set so that a broadband λ/4 plate can be realized by the combination of the λ/2 plate and a λ/4 plate. The specific in-plane retardation of the λ/2 plate is preferably 240 nm or more, and more preferably 242 nm or more, and is preferably 300 nm or less, more preferably 280 nm or less, and particularly preferably 265 nm or less. When the λ/2 plate has such an in-plane retardation, the λ/2 plate can function as a broadband λ/4 plate in combination with the λ/4 plate.

The λ/2 plate may have wavelength distribution properties such as forward wavelength distribution properties, flat wavelength distribution properties, and reverse wavelength distribution properties. The forward wavelength distribution properties mean wavelength distribution properties in which as the wavelength is shorter, the retardation is larger. The reverse wavelength distribution properties mean wavelength distribution properties in which as the wavelength is shorter, the retardation is smaller. The flat wavelength distribution properties mean wavelength distribution properties in which the retardation is not changed regardless of the wavelength.

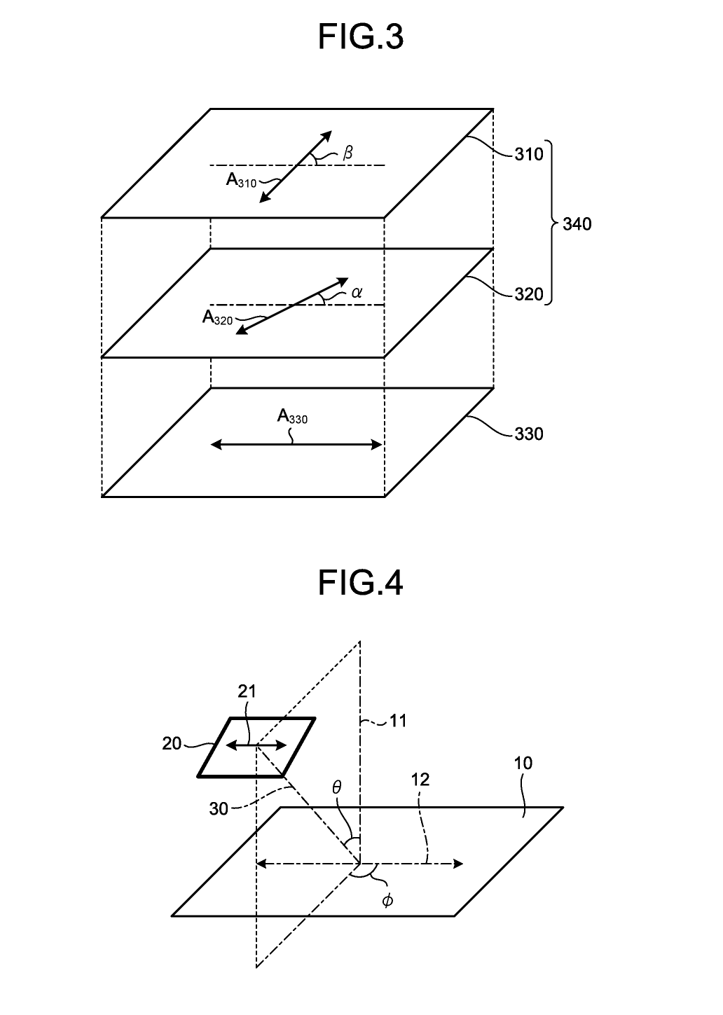

FIG. 3 is an exploded perspective view schematically illustrating a relationship of a λ/4 plate 310, a λ/2 plate 320, and a linear polarizer 330 in an image display device as an example of the present invention. In FIG. 3, a virtual line parallel to a polarized light absorption axis A₃₃₀ of the linear polarizer 330 is shown by a dot-and-dash line on the λ/4 plate 310 and the λ/2 plate 320.

Like the example illustrated in FIG. 3, the image display device of the present invention includes the λ/4 plate 310, the λ/2 plate 320, and the linear polarizer 330 in this order from the visual recognition side. In the example illustrated in FIG. 3, the λ/4 plate 310 corresponds to the λ/4 plates 170 and 260 according to the embodiments described above, the λ/2 plate 320 corresponds to the λ/2 plates 160 and 250 according to the embodiments described above, and the linear polarizer 330 corresponds to the visual recognition-side linear polarizer 140 and the linear polarizer 230 according to the embodiments described above (see FIGS. 1 and 2).

An angle a of a slow axis A₃₂₀ of the λ/2 plate 320 relative to the polarized light absorption axis A₃₃₀ of the linear polarizer 330 may be optionally set so that a broadband λ/4 plate 340 can be realized by the combination of the λ/2 plate 320 and the λ/4 plate 310. The specific range of the angle α is preferably 15°±5°, more preferably 15°±3°, and particularly preferably 15°±1°. When the angle α falls within the aforementioned range, the broadband λ/4 plate 340 including the λ/2 plate 320 and the λ/4 plate 310 in combination can stably convert linearly polarized light that has passed through the linear polarizer 330 and has a wide wavelength range into circularly polarized light. In particular, when the λ/2 plate 320 and the linear polarizer 330 each have a long-length shape and the angle α falls within the aforementioned range, bonding of the λ/2 plate 320 and the linear polarizer 330 can be easily performed by a roll-to-roll method.

It is preferable that the λ/2 plate is a member containing a thermoplastic resin. It is further preferable that the λ/2 plate is a resin film formed of a thermoplastic resin. It is preferable that the thermoplastic resin is a resin having a positive intrinsic birefringence value. Such a thermoplastic resin usually contains a thermoplastic polymer and if necessary, an optional component.

Examples of the polymer that the thermoplastic resin may contain may include polyolefins such as polyethylene and polypropylene; polyesters such as polyethylene terephthalate and polybutylene terephthalate; polyarylene sulfides such as polyphenylene sulfide; polyvinyl alcohol; polycarbonate; polyarylate; cellulose ester polymers, polyethersulfone; polysulfone; polyallylsulfone; polyvinyl chloride; cyclic olefin polymers such as a norbornene polymer; and rod-like liquid crystal polymers. As these polymers, one type thereof may be solely used, and two or more types thereof may also be used in combination at any ratio. The polymer may be a homopolymer or copolymer. Among these, because of excellent mechanical strength, heat resistance, transparency, low hygroscopicity, size stability, and light-weight property, cyclic olefin polymers are preferable.

The cyclic olefin polymer is a polymer having an alicyclic structure as the structural unit of the polymer. The cyclic olefin polymer may be a polymer having an alicyclic structure in its main chain, a polymer having an alicyclic structure in its side chain, a polymer having an alicyclic structure in its main and side chains, and a mixture of two or more of these polymers at any ratio. Among these, from the viewpoint of mechanical strength and heat resistance, a polymer having an alicyclic structure in its main chain is preferable.

Examples of the alicyclic structure may include a saturated alicyclic hydrocarbon (cycloalkane) structure, and an unsaturated alicyclic hydrocarbon (cycloalkene, cycloalkyne) structure. Among these, from the viewpoint of mechanical strength and heat resistance, a cycloalkane structure and a cycloalkene structure are preferable, and a cycloalkane structure is particularly preferable.

The number of carbon atoms constituting the alicyclic structure is preferably 4 or more, and more preferably 5 or more, and is preferably 30 or less, more preferably 20 or less, and particularly preferably 15 or less, per one alicyclic structure. When the number of carbon atoms constituting the alicyclic structure falls within this range, mechanical strength, heat resistance, and moldability of the resin are highly balanced.

The ratio of the structural unit having the alicyclic structure in the cyclic olefin polymer is preferably 55% by weight or more, further preferably 70% by weight or more, and particularly preferably 90% by weight or more. When the ratio of the structural unit having the alicyclic structure in the cyclic olefin polymer falls within this range, transparency and heat resistance are improved.

Among the cyclic olefin polymers, a cycloolefin polymer is preferable. The cycloolefin polymer is a polymer having a structure obtained by polymerizing a cycloolefin monomer. The cycloolefin monomer is a compound having a ring structure formed by carbon atoms and polymerizable carbon-carbon double bonds in its ring structure. Examples of the polymerizable carbon-carbon double bond may include carbon-carbon double bonds capable of being polymerized, such as ring-opening polymerization. Examples of the ring structure of the cycloolefin monomer may include a monocycle, a polycycle, a fused polycycle, a bridged ring, and polycycles obtained by combining these. Among these, a polycyclic cycloolefin monomer is preferable from the viewpoint of highly balanced properties of the obtained polymer such as dielectric properties and heat resistance.

Preferred examples of the above-described cycloolefin polymer may include a norbornene-based polymer, a monocyclic olefin-based polymer, a cyclic conjugated diene-based polymer, and hydrogenated products thereof. Among these, a norbornene-based polymer is particularly suitable because of its excellent moldability. Thus, as the thermoplastic resin contained in the λ/2 plate, a norbornene-based resin containing the norbornene-based polymer is preferable.

Examples of the norbornene-based polymer may include a ring-opening polymer of a monomer having a norbornene structure and a hydrogenated product thereof; and an addition polymer of a monomer having a norbornene structure and a hydrogenated product thereof. Examples of the ring-opening polymer of the monomer having a norbornene structure may include a ring-opening homopolymer of one type of monomer having a norbornene structure, a ring-opening copolymer of two or more types of monomers having a norbornene structure, and a ring-opening copolymer of a monomer having a norbornene structure with another monomer copolymerizable therewith. Examples of the addition polymer of the monomer having a norbornene structure may include an addition homopolymer of one type of monomer having a norbornene structure, an addition copolymer of two or more types of monomers having a norbornene structure, and an addition copolymer of a monomer having a norbornene structure with an optional monomer copolymerizable therewith. Among these, a hydrogenated product of a ring-opening polymer of a monomer having a norbornene structure is particularly suitable from the viewpoint of moldability, heat resistance, low hygroscopicity, size stability, light-weight property, and the like.

Examples of the monomer having a norbornene structure may include bicyclo[2.2.1]hept-2-ene (common name: norbornene), tricyclo[4.3.0.1^{2,5}]deca-3,7-diene (common name: dicyclopentadiene), 7,8-benzotricyclo[4.3.0.1^{2,5}]dec-3-ene (common name: methanotetrahydrofluorene), tetracyclo[4.4.0.1^{2,5}.1^{7,10}]dodeca-3-ene (common name: tetracyclododecene), and derivatives of these compounds (for example, those with a substituent on the ring). Examples of the substituent may include an alkyl group, an alkylene group, and a polar group. A plurality of these substituents, which may be the same as or different from each other, may be bonded to the ring. As the monomer having a norbornene structure, one type thereof may be solely used, and two or more types thereof may also be used in combination at any ratio.

Examples of the polar group may include a heteroatom, and an atomic group having a heteroatom. Examples of the heteroatom may include an oxygen atom, a nitrogen atom, a sulfur atom, a silicon atom, and a halogen atom. Specific examples of the polar group may include a carboxyl group, a carbonyloxycarbonyl group, an epoxy group, a hydroxyl group, an oxy group, an ester group, a silanol group, a silyl group, an amino group, an amido group, an imido group, a nitrile group, and a sulfonic acid group.

Examples of a monomer that is ring-opening copolymerizable with the monomer having a norbornene structure may include monocyclic olefins such as cyclohexene, cycloheptene, and cyclooctene, and derivatives thereof; and cyclic conjugated dienes such as cyclohexadiene and cycloheptadiene, and derivatives thereof. As the monomer that is ring-opening copolymerizable with the monomer having a norbornene structure, one type thereof may be solely used, and two or more types thereof may also be used in combination at any ratio.

The ring-opening polymer of the monomer having a norbornene structure may be produced, for example, by polymerizing or copolymerizing the monomer in the presence of a ring-opening polymerization catalyst.

Examples of a monomer that is addition copolymerizable with the monomer having a norbornene structure may include α-olefins of 2 to 20 carbon atoms such as ethylene, propylene, and 1-butene, and derivatives thereof; cycloolefins such as cyclobutene, cyclopentene, and cyclohexene, and derivatives thereof; and non-conjugated dienes such as 1,4-hexadiene, 4-methyl-1,4-hexadiene, and 5-methyl-1,4-hexadiene. Among these, α-olefin is preferable, and ethylene is more preferable. As the monomer that is addition copolymerizable with the monomer having a norbornene structure, one type thereof may be solely used, and two or more types thereof may also be used in combination at any ratio.

The addition polymer of the monomer having a norbornene structure may be produced, for example, by polymerizing or copolymerizing the monomer in the presence of an addition polymerization catalyst.

The above-mentioned hydrogenated products of the ring-opening polymer and the addition polymer may be produced, for example, by hydrogenating an unsaturated carbon-carbon bond, preferably 90% or more thereof, in a solution of the ring-opening polymer and the addition polymer in the presence of a hydrogenation catalyst containing a transition metal such as nickel, palladium, or the like.

Among the norbornene-based polymers, it is preferable that the polymer has an X: bicyclo[3.3.0]octane-2,4-diyl-ethylene structure and a Y: tricyclo[4.3.0.1^{2,5}]decane-7,9-diyl-ethylene structure as structural units, and that the amount of these structural units is 90% by weight or more relative to the entire structural unit of the norbornene-based polymer, and the content ratio of X and Y is 100:0 to 40:60 by weight ratio of X:Y. By using such a polymer, the λ/2 plate containing the norbornene-based polymer can be made to have excellent stability of optical properties without size change over a long period of time.

Examples of the monocyclic cyclic olefin-based polymer may include addition polymers of cyclic olefin-based monomers having a monocycle such as cyclohexene, cycloheptene, cyclooctene, and the like.

Examples of the cyclic conjugated diene polymer may include polymers obtained by cyclizing an addition polymer of a conjugated diene monomer such as 1,3-butadiene, isoprene, chloroprene, and the like; 1,2- or 1,4-addition polymers of a cyclic conjugated diene monomer such as cyclopentadiene, cyclohexadiene, and the like; and hydrogenated products thereof.

The weight-average molecular weight (Mw) of the polymer contained in the resin as a material for the λ/2 plate is preferably 10,000 or more, more preferably 15,000 or more, and particularly preferably 20,000 or more, and is preferably 100,000 or less, more preferably 80,000 or less, and particularly preferably 50,000 or less. When the weight-average molecular weight falls within this range, mechanical strength and moldability of the resin are highly balanced, and the resin is thus preferable. Herein, the weight-average molecular weight is a polyisoprene- or polystyrene-equivalent weight-average molecular weight measured by gel permeation chromatography using cyclohexane as a solvent. When the sample is not dissolved in cyclohexane, toluene may be used as the solvent in the gel permeation chromatography.

The molecular weight distribution (weight-average molecular weight (Mw)/number-average molecular weight (Mn)) of the polymer contained in the resin as a material for the λ/2 plate is preferably 1.2 or more, more preferably 1.5 or more, and particularly preferably 1.8 or more, and is preferably 3.5 or less, more preferably 3.0 or less, and particularly preferably 2.7 or less. When the molecular weight distribution is equal to or more than the lower limit value of the aforementioned range, productivity of the polymer can be improved and production cost can be suppressed. When the molecular weight distribution is equal to or less than the upper limit value, the amount of the low molecular component is reduced, so that the relaxation at the time of high temperature exposure can be suppressed, and the stability of the λ/2 plate can be enhanced.

The ratio of the polymer in the resin as a material for the λ/2 plate is preferably 50% by weight to 100% by weight, more preferably 70% by weight to 100% by weight, and particularly preferably 90% by weight to 100% by weight. When the ratio of the polymer falls within the aforementioned range, the λ/2 plate can have sufficient heat resistance and transparency.

The resin as a material for the λ/2 plate may contain an optional component in addition to the above-mentioned polymer. Examples of the optional components may include a colorant such as a dye and a pigment; a plasticizer; a fluorescent brightener; a dispersant; a heat stabilizer; a light stabilizer; an ultraviolet absorber; an antistatic agent; an antioxidant; a particulate, and a surfactant. As these components, one type thereof may be solely used, and two or more types thereof may also be used in combination at any ratio.

The glass transition temperature Tg₂ of the resin as a material for the λ/2 plate is preferably 100° C. or higher, more preferably 110° C. or higher, and particularly preferably 120° C. or higher, and is preferably 190° C. or lower, more preferably 180° C. or lower, and particularly preferably 170° C. or lower. When the glass transition temperature of the resin is equal to or higher than the lower limit value of the aforementioned range, durability of the λ/2 plate in a high temperature environment can be increased. When the glass transition temperature thereof is equal to or lower than the upper limit value, stretching treatment is facilitated.

The absolute value of the photoelastic coefficient of the resin as a material for the λ/2 plate is 10×10⁻¹² Pa⁻¹ or less, more preferably 7×10⁻¹² Pa⁻¹ or less, and particularly preferably 4×10⁻¹² Pa⁻¹ or less. By setting the photoelastic coefficient in this manner, it is possible to suppress the fluctuation in retardation of the λ/2 plate. Herein, the photoelastic coefficient C is a value represented by C=Δn/σ where Δn represents a birefringence and σ represents a stress.

The total light transmittance of the λ/2 plate is preferably 80% or more. The total light transmittance may be measured in accordance with JIS K0115 using a spectrophotometer (UV-visible/N-IR spectrometer “V-570” manufactured by JASCO Corporation).

The haze of the λ/2 plate is preferably 5% or less, more preferably 3% or less, particularly preferably 1% or less, and ideally 0%. Herein, the haze may be measured in accordance with JIS K7361-1997 using a “turbidimeter NDH-300A” manufactured by Nippon Denshoku Industries Co., Ltd., and an average value of values measured at 5 locations may be adopted as the haze.

The amount of the volatile component contained in the λ/2 plate is preferably 0.1% by weight or less, more preferably 0.05% by weight or less, further preferably 0.02% by weight or less, and ideally 0. When the amount of the volatile component is decreased, the size stability of the λ/2 plate can be improved and a change in optical properties such as retardation with the lapse of time can be reduced.

Herein, the volatile component is a substance having a molecular weight of 200 or less that is contained in a film in a trace amount, and examples thereof may include a residual monomer and a solvent. The amount of the volatile component may be quantified as the total amount of substances having a molecular weight of 200 or less contained in a film by dissolving the film in chloroform followed by analysis using gas chromatography.

The saturated water absorption ratio of the λ/2 plate is preferably 0.03% by weight or less, more preferably 0.02% by weight or less, particularly preferably 0.01% by weight or less, and ideally 0. When the saturated water absorption ratio of the λ/2 plate falls within the aforementioned range, a change in optical properties such as in-plane retardation with the lapse of time can be reduced.

Herein, the saturated water absorption ratio is a value expressed in percentage of an increased weight obtained by immersing a film test piece in water at 23° C. for 24 times to the weight of the film test piece before the immersion.

The thickness of the λ/2 plate is preferably 10 μm or more, more preferably 15 μm or more, and further preferably 30 μm or more, and is preferably 100 μm or less, more preferably 80 μm or less, and further preferably 60 μm or less. By having the thickness within this range, mechanical strength of the λ/2 plate can be enhanced.

The method for producing the λ/2 plate is optional. For example, the λ/2 plate may be produced as a diagonally stretched film by a production method including performing one or more diagonally stretching treatments of a long-length pre-stretch film formed of a resin. Herein, “diagonal stretching” means that a long-length film is stretched in a diagonal direction. According to the production method including the diagonal stretching, the λ/2 plate can be easily produced.

It is preferable that the λ/2 plate is produced as a sequentially biaxially stretched film by a production method including longitudinal stretching after the diagonal stretching. Herein, “longitudinal stretching” means that a long-length film is stretched in the lengthwise direction of the film. According to the combination of the diagonal stretching and the longitudinal stretching, a λ/2 plate capable of being bonded to a linear polarizer by a roll-to-roll method can be easily produced.

Hereinafter, a preferable example of the method for producing the λ/2 plate will be described. The method for producing the λ/2 plate according to this example includes (a) a first step of preparing a long-length pre-stretch film formed of a thermoplastic resin, (b) a second step of stretching the long-length pre-stretch film in a diagonal direction to obtain a long-length intermediate film, and (c) a third step of performing free uniaxial stretching of the intermediate film in a lengthwise direction to obtain a long-length λ/2 plate.

In the first step (a), the long-length pre-stretch film formed of a thermoplastic resin is prepared. The pre-stretch film may be produced, for example, by a melt molding method or a solution casting method. Specific examples of the melt molding method may include an extrusion molding method, a press molding method, an inflation molding method, an injection molding method, a blow molding method, and a stretch molding method. Among these methods, the extrusion molding method, the inflation molding method, and the press molding method are preferable for obtaining a λ/2 plate having excellent mechanical strength and surface precision, and the extrusion molding method is particularly preferable from the viewpoint of achieving efficient and easy production of the λ/2 plate.

After the long-length pre-stretch film is prepared in the first step (a), the second step (b) of stretching the long-length pre-stretch film in a diagonal direction to obtain the intermediate film is performed. In the second step, stretching is usually performed by a tenter stretching machine while the pre-stretch film is continuously conveyed in the lengthwise direction. The tenter stretching machine has a plurality of grippers capable of gripping respective ends in the widthwise direction of the pre-stretch film. When the pre-stretch film is stretched by the grippers in a specific direction, stretching in any optional direction can be achieved.

The stretching ratio in the second step (b) is preferably 1.1 times or more, more preferably 1.15 times or more, and particularly preferably 1.2 times or more, and is preferably 5.0 times or less, more preferably 4.0 times or less, and particularly preferably 3.5 times or less. When the stretching ratio in the second step (b) is equal to or more than the lower limit value of the aforementioned range, occurrence of wrinkles in the λ/2 plate can be suppressed and the refractive index in the stretching direction can be increased. When the stretching ratio is equal to or less than the upper limit value of the aforementioned range, fluctuation of the orientation angle and orientation direction of the λ/2 plate can be decreased and the slow axis direction can be easily controlled. The orientation angle and orientation direction may be measured by a polarized light microscope or Axoscan (manufactured by Axometrics, Inc.).

The stretching temperature in the second step (b) is preferably Tg₂−5° C. or higher, more preferably Tg₂−2° C. or higher, and particularly preferably Tg₂° C. or higher, and is preferably Tg₂+40° C. or lower, more preferably Tg₂+35° C. or lower, and particularly preferably Tg₂+30° C. or lower. Herein, Tg₂ is the glass transition temperature of the thermoplastic resin as a material for the λ/2 plate. When the stretching temperature in the second step (b) falls within the aforementioned range, molecules contained in the pre-stretch film can be reliably oriented. Therefore, an intermediate film having desired optical properties can be easily obtained.

As a result of the stretching in the second step (b), the molecules contained in the intermediate film are oriented. Therefore, the intermediate film has a slow axis. In the second step (b), stretching is performed in the diagonal direction. Therefore, the slow axis of the intermediate film is expressed in the diagonal direction of the intermediate film. Specifically, the intermediate film usually has the slow axis within a range of 5° to 85° relative to the lengthwise direction of the intermediate film.

It is preferable that a specific direction of the slow axis of the intermediate film is set depending on the direction of the slow axis of the λ/2 plate that is desired to be produced. The angle of the slow axis of the λ/2 plate obtained in the third step (c) relative to the lengthwise direction thereof is usually smaller than the angle of the slow axis of the intermediate film relative to the lengthwise direction thereof. Therefore, it is preferable that the angle of the slow axis of the intermediate film relative to the lengthwise direction thereof is larger than the angle of the slow axis of the λ/2 plate relative to the lengthwise direction thereof.

After the second step (b), the third step (c) of performing free uniaxial stretching of the intermediate film in the lengthwise direction to obtain the long-length λ/2 plate is performed. Herein, the free uniaxial stretching means stretching in a certain direction in which a restraint force is not applied in any directions other than the stretching direction. Therefore, the free uniaxial stretching in the lengthwise direction of the intermediate film shown in this example means stretching in the lengthwise direction without restraining ends in a widthwise direction of the intermediate film. Such stretching in the third step (c) is usually performed by a roll stretching machine while the intermediate film is continuously conveyed in the lengthwise direction.

It is preferable that the stretching ratio in the third step (c) is smaller than the stretching ratio in the second step (b). In this case, stretching can be performed for the λ/2 plate having a slow axis in the diagonal direction while occurrence of wrinkles is suppressed. When the stretching in the diagonal direction and the free uniaxial stretching in the lengthwise direction are performed in this order and the stretching ratio in the third step (c) is made smaller than the stretching ratio in the second step (b), a λ/2 plate having a slow axis in a direction in which the angle relative to the lengthwise direction is small can be easily produced.

Specifically, the stretching ratio in the third step (c) is preferably 1.1 times or more, more preferably 1.15 times or more, and particularly preferably 1.2 times or more, and is preferably 3.0 times or less, more preferably 2.8 times or less, and particularly preferably 2.6 times or less. When the stretching ratio in the third step (c) is equal to or more than the lower limit value of the aforementioned range, occurrence of wrinkles in the λ/2 plate can be suppressed. When the stretching ratio is equal to or less than the upper limit value of the aforementioned range, the slow axis direction can be easily controlled.

The stretching temperature T2 in the third step (c) is preferably higher than “T1−20° C.”, more preferably “T1−18° C.” or higher, and particularly preferably “T1−16° C.” or higher, and is preferably lower than “T1+20° C.”, more preferably “T1+18° C.” or lower, and particularly preferably “T1+16° C.” or lower, on the basis of the stretching temperature T1 in the second step (b). When the stretching temperature T2 in the third step (c) falls within the aforementioned range, the in-plane retardation of the λ/2 plate can be effectively adjusted.

The method for producing the λ/2 plate shown in the aforementioned example may be performed with modification.

For example, the method for producing the λ/2 plate may further include an optional step, in addition to the first step (a), the second step (b), and the third step (c). Examples of the optional step may include a step of providing a protective layer on a surface of the λ/2 plate and a step of performing a surface treatment such as a chemical treatment and a physical treatment on the surface of the λ/2 plate.

For example, a film obtained by stretching a pre-stretch film in an optional direction may be used as the pre-stretch film. As the method for stretching the pre-stretch film before the second step (b), a roll style or float style longitudinal stretching method or a lateral stretching method using a tenter stretching machine may be used.

[3. λ/4 plate]

In the following, a λ/4 plate such as the λ/4 plates 170 and 260 according to the embodiments illustrated in FIGS. 1 and 2 will be described.

The in-plane retardation of the λ/4 plate may be appropriately set in a range wherein a broadband λ/4 plate can be realized by the combination of the λ/2 plate and the λ/4 plate. The specific in-plane retardation of the λ/4 plate is preferably 110 nm or more, and more preferably 118 nm or more, and is preferably 154 nm or less, more preferably 138 nm or less, and particularly preferably 128 nm or less. When the λ/4 plate has such an in-plane retardation, the combination of the λ/2 plate and the λ/4 plate can function as a broadband λ/4 plate.

The NZ factor NZq of the λ/4 plate is preferably 0.95 or more, more preferably 0.97 or more, and particularly preferably 0.99 or more, and is preferably 1.05 or less, more preferably 1.03 or less, and particularly preferably 1.01 or less. When the NZ factor NZq of the λ/4 plate is close to 1.0 and optical uniaxial property is high, the λ/4 plate in combination with the λ/2 plate having an NZ factor NZh within the specific range can favorably function as a broadband λ/4 plate.

The λ/4 plate may have wavelength distribution properties such as forward wavelength distribution properties, flat wavelength distribution properties, and reverse wavelength distribution properties.

In general, when a multilayer film that is a combination of a λ/4 plate having a slow axis at an angle θ_{λ/4} relative to a certain reference direction and a λ/2 plate having a slow axis at an angle θ_{λ/2} relative to the reference direction satisfies expression C: “θ_{λ/4}=2θ_{λ/2}+45°”, the multilayer film acts as a broadband λ/4 plate which can give light passing through the multilayer film an in-plane retardation of approximately ¼ wavelength of the light in a wide wavelength range (see Japanese Patent Application Laid-Open No. 2007-004120 A).

From the viewpoint of exerting a function of the broadband λ/4 plate 340 by the combination of the λ/2 plate 320 and the λ/4 plate 310 as illustrated in FIG. 3, it is preferable that the relationship between the slow axis A₃₁₀ of the λ/4 plate 310 and the slow axis A₃₂₀ of the λ/2 plate 320 in the image display device of the present invention satisfies a relationship that is close to expression C. Specifically, the angle β of the slow axis A₃₁₀ of the λ/4 plate 310 relative to the polarized light absorption axis A₃₃₀ of the linear polarizer 330 is preferably (2α+45°)±5°, more preferably (2α+45°)±3°, and particularly preferably (2α+45°)±1°. Herein, the angle α is an angle of the slow axis A₃₂₀ of the λ/2 plate 320 relative to the polarized light absorption axis A₃₃₀ of the linear polarizer 330.

Herein, the direction of the angle β of the slow axis A₃₁₀ of the λ/4 plate 310 relative to the polarized light absorption axis A₃₃₀ of the linear polarizer 330 is usually the same as the direction of the angle α of the slow axis A₃₂₀ of the λ/2 plate 320 relative to the polarized light absorption axis A₃₃₀ of the linear polarizer 330. For example, when the angle a of the slow axis A₃₂₀ of the λ/2 plate 320 relative to the polarized light absorption axis A₃₃₀ of the linear polarizer 330 is formed in a direction of the clockwise rotation as viewed in a thickness direction, the angle β of the slow axis A310 of the λ/4 plate 310 relative to the polarized light absorption axis A₃₃₀ of the linear polarizer 330 is usually formed in a direction of the clockwise rotation. As another example, when the angle α of the slow axis A₃₂₀ of the λ/2 plate 320 relative to the polarized light absorption axis A₃₃₀ of the linear polarizer 330 is formed in a direction of the counterclockwise rotation as viewed in the thickness direction, the angle β of the slow axis A₃₁₀ of the λ/4 plate 310 relative to the polarized light absorption axis A₃₃₀ of the linear polarizer 330 is usually formed in a direction of the counterclockwise rotation.

It is preferable that the λ/4 plate is a member containing a thermoplastic resin. It is further preferable that the λ/4 plate is a resin film formed of a thermoplastic resin. As the thermoplastic resin of the λ/4 plate, one optionally selected from the thermoplastic resins described as the material for the λ/2 plate may be used. Thereby the same advantage as described in the section of λ/2 plate can also be obtained in the λ/4 plate. In particular, it is preferable that the thermoplastic resin of the λ/4 plate is a norbornene-based resin. As the norbornene-based resin, various products are commercially available. Specific examples thereof may include trade name “ZEONOR” available from ZEON Corporation, trade name “ARTON” available from JSR Corporation, trade name “TOPAS” available from TICONA, and trade name “APEL” available from Mitsui Chemicals, Inc.

The thermoplastic resin contained in the λ/2 plate and the thermoplastic resin contained in the λ/4 plate may be different from each other. However, it is preferable that thermoplastic resins are the same as each other. Thereby, even when the broadband λ/4 plate including the λ/2 plate and the λ/4 plate is used in an on-vehicle application and placed in a high-temperature environment, the sizes of the λ/2 plate and the λ/4 plate changes at the same degree in the same direction. Therefore, a broadband λ/4 plate that is unlikely to be thermally deformed can be realized.

The total light transmittance of the λ/4 plate is preferably 80% or more.

The haze of the λ/4 plate is preferably 5% or less, more preferably 3% or less, particularly preferably 1% or less, and ideally 0%.

The amount of a volatile component contained in the λ/4 plate is preferably 0.1% by weight or less, more preferably 0.05% by weight or less, further preferably 0.02% by weight or less, and ideally 0. When the amount of the volatile component is decreased, size stability of the λ/4 plate can be improved and a change in optical properties such as retardation with the lapse of time can be reduced.

The saturated water absorption ratio of the λ/4 plate is preferably 0.03% by weight or less, more preferably 0.02% by weight or less, particularly preferably 0.01% by weight or less, and ideally 0. When the saturated water absorption ratio of the λ/4 plate falls within the aforementioned range, a change in optical properties such as in-plane retardation with the lapse of time can be reduced.

The thickness of the λ/4 plate is preferably 10 μm or more, more preferably 15 μm or more, and particularly preferably 20 μm or more, and is preferably 80 μm or less, more preferably 60 μm or less, and particularly preferably 50 μm or less. When the thickness of the λ/4 plate is equal to or more than the lower limit value of the aforementioned range, a desired retardation can be easily exerted. When it is equal to or less than the upper limit value thereof, the thickness of the film can be decreased.

The method for producing the λ/4 plate is optional. For example, the λ/4 plate may be produced as a stretched film by a production method including stretching a long-length pre-stretch film formed of a resin.

Preferable examples of the method for producing the λ/4 plate may include a production method including (d) a fourth step of preparing a long-length pre-stretch film formed of a thermoplastic resin, and (e) a fifth step of stretching the long-length pre-stretch film to obtain a long-length λ/4 plate.

In the fourth step (d), a long-length pre-stretch film formed of a thermoplastic resin is prepared. For example, the pre-stretch film may be produced by the same method as the first step (a) in the method for producing the λ/2 plate. When in the fourth step (d), the pre-stretch film is produced by the same method as that in the first step (a), the same advantage as that of the first step (a) is also obtained in the fourth step (d).

After the long-length pre-stretch film is prepared in the fourth step (d), the fifth step (e) of stretching the long-length pre-stretch film to obtain the λ/4 plate is performed. In the fifth step, stretching is usually performed while the pre-stretch film is continuously conveyed in the lengthwise direction. In this case, the stretching direction may be a lengthwise direction, a widthwise direction, or a diagonal direction of the film. The stretching may be free uniaxial stretching in which a restraint force is applied in only the stretching direction, or stretching in which a restraint force is applied in another direction in addition to the stretching direction. The stretching may be performed by any stretching machine such as a roll stretching machine and a tenter stretching machine.

The stretching ratio in the fifth step (e) is preferably 1.1 times or more, more preferably 1.15 times or more, and particularly preferably 1.2 times or more, and is preferably 3.0 times or less, more preferably 2.8 times or less, and particularly preferably 2.6 times or less. When the stretching ratio in the fifth step (e) is equal to or more than the lower limit value of the aforementioned range, the refractive index in the stretching direction can be increased. When the stretching ratio is equal to or less than the upper limit value, the slow axis direction of the λ/4 plate can be easily controlled.

The stretching temperature in the fifth step (e) is preferably Tg₄−5° C. or higher, more preferably Tg₄−2° C. or higher, and particularly preferably Tg₄° C. or higher, and is preferably Tg₄+40° C. or lower, more preferably Tg₄+35° C. or lower, and particularly preferably Tg₄+30° C. or lower. Herein, Tg₄ is the glass transition temperature of the thermoplastic resin as a material for the λ/4 plate. When the stretching temperature in the fifth step (e) falls within the aforementioned range, molecules contained in the pre-stretch film can be reliably oriented. Consequently, a λ/4 plate having desired optical properties can be easily obtained.

The method for producing the λ/4 plate shown in the aforementioned example may be performed with modification. For example, the method for producing the λ/4 plate may further include an optional step, in addition to the fourth step (d) and the fifth step (e). For example, the method for producing the λ/4 plate may include a step of trimming both ends of the produced λ/4 plate and a step of performing a surface treatment such as a chemical treatment and a physical treatment on a surface of the λ/4 plate. The method for producing the λ/4 plate may include the same step as the optional step in the method for producing the λ/2 plate.

[4. Linear Polarizer]

In the following, a linear polarizer such as the visual recognition-side linear polarizer 140 and the linear polarizer 230 according to the embodiments illustrated in FIGS. 1 and 2 will be described.

The linear polarizer is an optical member having a polarized light transmission axis and a polarized light absorption axis. The linear polarizer may absorb linearly polarized light having a vibration direction parallel to the polarized light absorption axis and allow to pass therethrough linearly polarized light having a vibration direction parallel to the polarized light transmission axis. In the image display device, linearly polarized light having passed through this linear polarizer is allowed to pass through the broadband λ/4 plate including the λ/2 plate and the λ/4 plate in combination, resulting in circularly polarized light. The circularly polarized light travels to the outside of the image display device. Thus, light for displaying an image is visually recognized by an observer.

The linear polarizer for use may be a film obtained by giving appropriate treatments such as a dyeing treatment by iodine or a dichroic substance such as a dichroic dye, a stretching treatment, and a cross-linking treatment in an appropriate order by an appropriate procedure to a film of appropriate vinyl alcohol-based polymer such as polyvinyl alcohol and partially formalized polyvinyl alcohol. In a stretching treatment for producing a linear polarizer, a film is usually stretched in the lengthwise direction of the film. Therefore, the linear polarizer to be obtained may express a polarized light absorption axis parallel to the lengthwise direction of the linear polarizer and a polarized light transmission axis parallel to the widthwise direction of the linear polarizer. It is preferable that this linear polarizer has excellent degree of polarization. The thickness of the linear polarizer is generally 5 μm to 80 μm, but is not limited to this range.

When a long-length linear polarizer is produced, it is preferable that the polarized light absorption axis of the linear polarizer is parallel to the lengthwise direction of the linear polarizer. When the long-length linear polarizer having such a feature is bonded to the long-length λ/2 plate and the long-length λ/4 plate, optical axes thereof can be matched to each other by making the lengthwise directions thereof parallel. Therefore, the long-length linear polarizer, the long-length λ/2 plate, and the long-length λ/4 plate can be easily bonded by a roll-to-roll method.

Bonding by a roll-to-roll method is a manner of bonding wherein a film is fed from a roll of a long-length film and conveyed, the film is bonded to another film on a conveyance line, and the bonded product is wound up to be a roll. In the bonding by a roll-to-roll method, a complicated step of matching optical axes is not necessary, which is different from a case where films in a sheet piece shape are bonded. Therefore, bonding can be efficiently performed.

[5. Image Display Element]

Examples of the image display element may include a liquid crystal cell and an organic EL element. In the image display device, an image may be controlled by the image display element. For example, in the liquid crystal display device 100 illustrated in FIG. 1, usually the liquid crystal cell 130 controls the amount of passage of light emitted from the light source 110 through the visual recognition-side linear polarizer 140. Thus, controlling of the image to be displayed is performed. In the organic EL display device 200 illustrated in FIG. 2, usually the organic EL element 210 controls the amount of light emitted from the organic EL element 210. Thus, controlling of the image to be displayed is performed.

As the liquid crystal cell, for example, a liquid crystal cell in any optional mode such as an in-plane switching (IPS) mode, a vertical alignment (VA) mode, a multi-domain vertical alignment (MVA) mode, a continuous pinwheel alignment (CPA) mode, a hybrid alignment nematic (HAN) mode, a twisted nematic (TM) mode, a super twisted nematic (STN) mode, and an optical compensated bend (OCB) mode may be used.

The organic EL element includes a transparent electrode layer, a light-emitting layer, and an electrode layer in this order. When an electric voltage is applied from the transparent electrode layer and the electrode layer, light may be generated by the light-emitting layer. Examples of a material constituting an organic light-emitting layer may include a poly(p-phenylene vinylene)-based material, a polyfluorene-based material, and a polyvinyl carbazole-based material. The light-emitting layer may have a layered body having a plurality of layers of different light-emitting colors or a mixed layer in which a layer of a dye is doped with a different dye. The organic EL element may include a functional layer such as a hole injection layer, a hole transport layer, an electron injection layer, an electron transport layer, an equipotential surface forming layer, and a charge generating layer.

[6. Optional Component]

The image display device may include an optional component in addition to the aforementioned components. Examples of the optional component may include a protective film for protecting a linear polarizer; an adhesive layer or tackiness agent layer for bonding films; a glass for suppressing scratch of a film; a hardcoat layer; an antireflective layer; and an antifouling layer.

### EXAMPLE

Hereinafter, the present invention will be specifically described by illustrating Examples. However, the present invention is not limited to the Examples described below. The present invention may be optionally modified for implementation without departing from the scope of claims of the present invention and the scope of their equivalents. In the following description, “%” and “part” representing quantity are on the basis of weight, unless otherwise specified. The operation described below was performed under the condition of normal temperature and normal pressure in the atmospheric air, unless otherwise specified.

[Evaluation Method]

[Method for Measuring Retardation and NZ factor]

The in-plane retardation Re, thickness-direction retardation Rth, and NZ factor of the films were measured by a phase difference measurement device (“AxoScan” manufactured by Axometrics, Inc.) at a measurement wavelength of 590 nm.

[Method for Calculating Color Difference ΔE*ab By Simulation]

The following evaluation model including a broadband λ/4 plate produced in each of Examples and Comparative Examples was set up by using software for simulation “LCD Master” manufactured by Shintech.

In the evaluation model for simulation, an image display device obtained by bonding a surface on a side of a λ/2 plate of the broadband λ/4 plate produced in each of Examples and Comparative Examples to a display surface of a commercially available liquid crystal display device (“iPad Air” manufactured by Apple Inc.) including a light source, a light source-side linear polarizer, a liquid crystal cell, and a visual recognition-side linear polarizer in this order was set up. The manner of bonding was set up such that the angles α and β of a λ/2 plate and a λ/4 plate, respectively, relative to a polarized light absorption axis of the visual recognition-side linear polarizing plate as viewed in the thickness direction were values shown in Table 1. The image display device included the λ/4 plate, the λ/2 plate, the visual recognition-side linear polarizer, and the liquid crystal cell as an image display element in this order from a visual recognition side.

FIG. 4 is a perspective view schematically illustrating a state of the evaluation model that was set up for calculation of chromaticity in the simulations in Examples and Comparative Examples.

A white image was assumed to be displayed on the image display device. When a display device 10 was viewed in an inclined direction of polar angle θ of 45° as illustrated in FIG. 4, (i) the chromaticity of the image viewed through a polarized sunglass 20 and (ii) the chromaticity of the image viewed without the polarized sunglass 20 were calculated. For the polarized sunglass 20, an ideal polarizing film having a polarized light absorption axis 21 in a horizontal direction and a flat shape perpendicular to a visual line 30 was set. Herein, the polar angle θ represents an angle formed relative to a normal direction 11 of the display surface 10. The ideal polarizing film is a film which allows to pass therethrough all linearly polarized light having a vibration direction parallel to a certain direction and does not allow at all to pass therethrough linearly polarized light having a vibration direction perpendicular to the direction. The color difference ΔE*ab was determined by the aforementioned expression (1) from (i) the chromaticity of an image viewed through the polarized sunglass 20 and (ii) the chromaticity of an image viewed without the polarized sunglass 20.

The calculation of the color difference ΔE*ab was performed at an interval of azimuth angle direction of 5° within a range of azimuth angle φ of 0° or more and less than 360°. Herein, the azimuth angle φ represents an angle of the direction parallel to the display surface 10 relative to a certain reference direction 12 parallel to the display surface 10. The average of the calculated color difference ΔE*ab was calculated as an average color difference.

[Visual Evaluation Method]

A commercially available liquid crystal display device (“iPad” manufactured by Apple Inc.) including a light source, a light source-side linear polarizing plate, a liquid crystal cell, and a visual recognition-side linear polarizing plate in this order was prepared. A display surface portion of the liquid crystal display device was disassembled and the visual recognition-side linear polarizing plate of the liquid crystal display device was exposed. To the exposed visual recognition-side linear polarizing plate, a surface on a λ/2 plate side of the broadband λ/4 plate produced in each of Examples and Comparative Examples was bonded to obtain an image display device. The bonding was performed such that the angles α and β of the λ/2 plate and a λ/4 plate, respectively, relative to the polarized light absorption axis of the visual recognition-side linear polarizing plate as viewed in the thickness direction were values shown in Table 1. The image display device included the λ/4 plate, the λ/2 plate, the visual recognition-side linear polarizing plate, and the liquid crystal cell as an image display element in this order from a visual recognition side.

A white image was displayed on the image display device. The image was observed in an inclined direction of polar angle of 45° relative to the display surface with the naked eye. Subsequently, the image was observed in the inclined direction of polar angle of 45° relative to the display surface through polarized sunglasses. The observations were performed in directions of all azimuth angles. The image viewed through polarized sunglasses was evaluated about a change in color and brightness by comparison with the image viewed without polarized sunglasses. As a difference in color and brightness between the image viewed through polarized sunglasses and the image viewed without polarized sunglasses is smaller in comparison, the result is more favorable.

The evaluation was performed by a large number of observers. Each observer ranked the results in all Examples and Comparative Examples gave points corresponding to the ranking (first place: 12 points, second place: 11 points, . . . , last place: 1 point). The totals of the points determined by the observers in Examples and Comparative Examples were sorted in the order of points. The points within the range were evaluated as A, B, C, D, and E in the decreasing order.

### Example 1

### (1-1. Production of λ/2 Plate)

A long-length pre-stretch film was prepared by a melt extrusion method from a norbornene-based resin (“ZEONOR” available from ZEON Corporation, glass transition temperature Tg: 126° C.) as a thermoplastic resin.

While the pre-stretch film was continuously conveyed in a lengthwise direction, the pre-stretch film was stretched in a diagonal direction of angle of 40° relative to the lengthwise direction at a stretching temperature of 140° C. and a stretching ratio of 1.65 times by using a tenter stretching machine including grippers for gripping ends of the film. As a result, an intermediate film was obtained.

While the intermediate film was continuously conveyed in the lengthwise direction, the intermediate film was subjected to free uniaxial stretching in the lengthwise direction at a stretching temperature of 135° C. and a stretching ratio of 1.45 times. As a result, a long-length λ/2 plate (thickness: 35 μm) was obtained. The obtained λ/2 plate had a slow axis in a direction of angle of 15.0° relative to the lengthwise direction thereof. The retardations Re and Rth and NZ factor NZh of the λ/2 plate were measured by the aforementioned methods.

(1-2. Production of λ/4 Plate)

A long-length pre-stretch film was produced by a melt extrusion method from a norbornene-based resin that was the same as one used in Production of λ/2 plate.

While the pre-stretch film was continuously conveyed in the lengthwise direction, the pre-stretch film was subjected to free uniaxial stretching in the lengthwise direction at a stretching temperature of 140° C. and a stretching ratio of 1.30 times. As a result, a long-length λ/4 plate (thickness: 30 μm) was obtained. The obtained λ/4 plate had a slow axis in a direction parallel to the lengthwise direction thereof. The retardations Re and Rth and NZ factor NZq of the λ/4 plate were measured by the aforementioned methods.

(1-3. Production of Broadband λ/4 Plate)

The long-length λ/2 plate and the long-length λ/4 plate obtained as the aforementioned manner were each cut into film pieces. The film pieces were bonded to each other by using a tackiness agent (“CS9621” available from Nitto Denko Corporation) to produce a broadband λ/4 plate. The bonding was performed such that the slow axis of the film piece of the λ/2 plate and the slow axis of the film piece of the λ/4 plate formed an angle of 60.0° as viewed in the thickness direction.

The resulting broadband λ/4 plate was evaluated by the aforementioned method. In the evaluation, the broadband λ/4 plate and the visual recognition-side linearly polarizing plate of the liquid crystal display device were bonded using a tackiness agent (“CS9621” available from Nitto Denko Corporation) so that the slow axis of the λ/2 plate and the absorption axis of the visual recognition-side polarizing plate formed an angle of 15° as viewed in the thickness direction.

### Examples 2 to 4

A broadband λ/4 plate was produced in the same manner as that of Example 1 except that stretching conditions (stretching temperature, stretching ratio, etc.) for the pre-stretch film and the intermediate film during production of a λ/2 plate were changed and thereby the thickness-direction retardation Rth and NZ factor NZh of the λ/2 plate were changed to values shown in Table 1. The broadband λ/4 plate was evaluated by the aforementioned method.

### Example 5

### (5-1. Production of λ/2 Plate)

A long-length λ/2 plate was produced in the same manner as that of the step (1-1) in Example 1.

(5-2. Production of λ/4 Plate)

A long-length pre-stretch film was produced by a melt extrusion method from a norbornene-based resin that was the same as one used in production of λ/2 plate in Example 1.

While the pre-stretch film was continuously conveyed in the lengthwise direction, the pre-stretch film was stretched in a diagonal direction of angle of 75° relative to the lengthwise direction at a stretching temperature of 142° C. and a stretching ratio of 5.0 times by using a tenter stretching machine including grippers for gripping ends of the film. As a result, a long-length λ/4 plate (thickness: 20 μm) was obtained. The obtained λ/4 plate had a slow axis in a direction of angle of 75.0° relative to the lengthwise direction thereof. The retardations Re and Rth and NZ factor NZq of the λ/4 plate were measured by the aforementioned methods.

(5-3. Production of Broadband λ/4 Plate)

The long-length λ/2 plate and the long-length λ/4 plate as described above were bonded to each other by a roll-to-roll method using a tackiness agent (“CS9621” available from Nitto Denko Corporation) to produce a broadband λ/4 plate. The bonding was performed so that the slow axis of the λ/2 plate and the slow axis of the λ/4 plate formed an angle of 60.0° as viewed in the thickness direction by making the lengthwise direction of the λ/2 plate parallel to the lengthwise direction of the λ/4 plate.

The resulting broadband λ/4 plate was evaluated by the aforementioned method.

### Examples 6 to 8

A broadband λ/4 plate was produced in the same manner as that of Example 5 except that stretching conditions (stretching temperature, stretching ratio, etc.) for the pre-stretch film and the intermediate film during production of a λ/2 plate were changed and thereby the thickness-direction retardation Rth and NZ factor NZh of the λ/2 plate were changed to values shown in Table 1. The broadband λ/4 plate was evaluated by the aforementioned method.

### Comparative Example 1

A long-length pre-stretch film was produced by a melt extrusion method from a norbornene-based resin that was the same as one used in production of λ/2 plate in Example 1.

While the pre-stretch film was continuously conveyed in the lengthwise direction, the pre-stretch film was subjected to free uniaxial stretching in the lengthwise direction at a stretching temperature of 135° C. and a stretching ratio of 1.6 times. As a result, a long-length λ/2 plate (thickness: 35 μm) was obtained. The obtained λ/2 plate had a slow axis in a direction parallel to the lengthwise direction thereof. The retardations Re and Rth and NZ factor NZh of the λ/2 plate were measured by the aforementioned methods.

A broadband λ/4 plate was produced in the same manner as that of Example 1 except that the λ/2 plate thus produced was used in place of the λ/2 plate produced in Example 1. The broadband λ/4 plate was evaluated by the aforementioned method.

### Comparative Example 2

The λ/2 plate produced in Comparative Example 1 was used in place of the λ/2 plate produced in Example 1. The λ/4 plate produced in Example 5 was used in place of the λ/4 plate produced in Example 1. A broadband λ/4 plate was produced in the same manner as that of Example 1 except for the aforementioned items.

### Comparative Example 3

A broadband λ/4 plate was produced in the same manner as that of Example 1 except that stretching conditions (stretching temperature, stretching ratio, etc.) for the pre-stretch film and the intermediate film during production of a λ/2 plate were changed and thereby the thickness-direction retardation Rth and NZ factor NZh of the λ/2 plate were changed to values shown in Table 1. The broadband λ/4 plate was evaluated by the aforementioned method.

### Comparative Example 4

Stretching conditions (stretching temperature, stretching ratio, etc.) for the pre-stretch film and the intermediate film during production of a λ/2 plate were changed and thereby the thickness-direction retardation Rth and NZ factor NZh of the λ/2 plate were changed to values shown in Table 1. The λ/4 plate produced in Example 5 was used in place of the λ/4 plate produced in Example 1. A broadband λ/4 plate was produced in the same manner as that of Example 1 except for the aforementioned items. The broadband λ/4 plate was evaluated by the aforementioned method.

[Results]

The results in Examples and Comparative Examples are shown in the following Table 1. Abbreviations in Table 1 mean as follows.

Re: in-plane retardation.

Rth: thickness-direction retardation.

NZh: NZ factor of λ/2 plate.

NZq: NZ factor of λ/4 plate.

α: angle of slow axis of λ/2 plate relative to polarized light absorption axis of visual recognition-side linear polarizer as viewed in the thickness direction.

β: angle of slow axis of λ/4 plate relative to polarized light absorption axis of visual recognition-side linear polarizer as viewed in the thickness direction.

Diagonal/lengthwise: free uniaxial stretching in the lengthwise direction was performed after diagonal stretching.

Diagonal: diagonal stretching was performed.

Lengthwise: free uniaxial stretching in the lengthwise direction was performed.

Batch: a film piece of λ/2 plate and a film piece of λ/4 plate were bonded.

Roll to Roll: a long-length λ/2 plate and a long-length λ/4 plate were bonded by a roll-to-roll method.

TABLE 1
[Results of Examples and Comparative Example]

| | λ/2 plate | | | | | λ/4 Plate | | | | | | | |
|---|---|---|---|---|---|---|---|---|---|---|---|---|---|
| | Re | Rth | | α | | Re | Rth | | β | | Manner of | Result | |
| | (nm) | (nm) | NZh | (°) | Stretching | (nm) | (nm) | NZq | (°) | Stretching | bonding | ΔE*ab | Visual |
| Ex. 1 | 245 | 245 | 1.5 | 15.0 | Diagonal/lengthwise | 122 | 61 | 1.0 | 75.0 | Lengthwise | Batch | 15.8 | C |
| Ex. 2 | 245 | 367 | 2.0 | 15.0 | Diagonal/lengthwise | 122 | 61 | 1.0 | 75.0 | Lengthwise | Batch | 13.7 | B |
| Ex. 3 | 245 | 489 | 2.5 | 15.0 | Diagonal/lengthwise | 122 | 61 | 1.0 | 75.0 | Lengthwise | Batch | 13.0 | A |
| Ex. 4 | 245 | 612 | 3.0 | 15.0 | Diagonal/lengthwise | 122 | 61 | 1.0 | 75.0 | Lengthwise | Batch | 13.9 | B |
| Ex. 5 | 245 | 245 | 1.5 | 15.0 | Diagonal/lengthwise | 122 | 85 | 1.2 | 75.0 | Diagonal | Roll to Roll | 15.9 | C |
| Ex. 6 | 245 | 367 | 2.0 | 15.0 | Diagonal/lengthwise | 122 | 85 | 1.2 | 75.0 | Diagonal | Roll to Roll | 13.9 | B |
| Ex. 7 | 245 | 489 | 2.5 | 15.0 | Diagonal/lengthwise | 122 | 85 | 1.2 | 75.0 | Diagonal | Roll to Roll | 13.4 | A |
| Ex. 8 | 245 | 612 | 3.0 | 15.0 | Diagonal/lengthwise | 122 | 85 | 1.2 | 75.0 | Diagonal | Roll to Roll | 14.5 | B |
| Comp. Ex. 1 | 245 | 122 | 1.0 | 15.0 | Lengthwise | 122 | 61 | 1.0 | 75.0 | Lengthwise | Batch | 19.0 | E |
| Comp. Ex. 2 | 245 | 122 | 1.0 | 15.0 | Lengthwise | 122 | 85 | 1.2 | 75.0 | Diagonal | Batch | 19.1 | E |
| Comp. Ex. 3 | 245 | 171 | 1.2 | 15.0 | Diagonal/lengthwise | 122 | 61 | 1.0 | 75.0 | Lengthwise | Batch | 17.6 | D |
| Comp. Ex. 4 | 245 | 171 | 1.2 | 15.0 | Diagonal/lengthwise | 122 | 85 | 1.2 | 75.0 | Diagonal | Batch | 17.7 | D |

[Discussion]

As shown in Table 1, in Examples 1 to 8 in which the NZ factor of the λ/2 plate is 1.5 or more, the color difference ΔE*ab is smaller than those in Comparative Examples 1 to 4. It was confirmed therefrom that, according to the present invention, an image display device capable of improving the visibility of an image viewed in an inclined direction of a display surface through polarized sunglasses can be realized. As seen from comparison of the results of Examples 1 to 8, the closer to 2.5 the NZ factor NZh of the λ/2 plate is, the lower the color difference ΔE*ab can be. Further, the results in visual evaluation are favorable. It was confirmed therefrom that a particularly preferable range of NZ factor NZh of the λ/2 plate is close to 2.5.

### REFERENCE SIGN LIST

10 display surface

11 normal direction of display surface

12 reference direction parallel to display surface

20 polarized sunglass

21 polarized light absorption axis of polarized sunglass

30 visual line

100 liquid crystal display device

100U display surface of liquid crystal display device

110 light source

120 light source-side linear polarizer

130 liquid crystal cell

140 visual recognition-side linear polarizer

150 liquid crystal panel

160 λ/2 plate

170 λ/4 plate

180 broadband λ/4 plate

200 organic EL display device

200U display surface of organic EL display device

210 organic EL element

220 λ/4 plate

230 linear polarizer

240 circularly polarizing plate

250 λ/2 plate

260 λ/4 plate

270 broadband λ/4 plate

310 λ/4 plate

320 λ/2 plate

330 linear polarizer

340 broadband λ/4 plate

1. An image display device comprising a λ/4 plate, a λ/2 plate, a linear polarizer, and an image display element disposed in this order from a visual recognition side, wherein
the λ/2 plate has an NZ factor NZh satisfying 1.5≤NZh.

2. The image display device according to claim 1, wherein the NZ factor NZh of the λ/2 plate satisfies 1.5≤NZh≤3.0.

3. The image display device according to claim 1, wherein the λ/4 plate has an NZ factor NZq satisfying 0.95≤NZq≤1.05.

4. The image display device according to claim 1, wherein when an angle of a slow axis of the λ/2 plate relative to a polarized light absorption axis of the linear polarizer is represented by α,
an angle of a slow axis of the λ/4 plate relative to the polarized light absorption axis of the linear polarizer is (2α+45°)±5°.

5. The image display device according to claim 1, wherein an angle α of a slow axis of the λ/2 plate relative to a polarized light absorption axis of the linear polarizer is 15°±5°.

6. The image display device according to claim 1, wherein the λ/2 plate and the λ/4 plate contain the same thermoplastic resin.

7. The image display device according to claim 1, wherein the λ/2 plate and the λ/4 plate contain a norbornene-based resin.

8. The image display device according to claim 1, wherein the λ/2 plate is a diagonally stretched film.

9. The image display device according to claim 1, wherein the λ/2 plate is a sequentially biaxially stretched film.

10. The image display device according to claim 1, wherein the image display element is any of a liquid crystal cell and an organic electroluminescent element.
